(19) United States
(12) Patent Application Publication
(10) Pub. No.: US 2025/0232077 A1
(43) Pub. Date: Jul. 17, 2025

(54) METHOD FOR RUNWAY CONFIGURATIONS PREDICTION OF MULTI-AIRPORT SYSTEM BASED ON DYNAMIC GRAPHS

(71) Applicant: BEIHANG UNIVERSITY, Beijing (CN)

(72) Inventors: Yang YANG, Beijing (CN); Kaiquan CAI, Beijing (CN); Qihan DENG, Beijing (CN); Minghua ZHANG, Beijing (CN)

(21) Appl. No.: 18/648,365

(22) Filed: Apr. 27, 2024

(30) Foreign Application Priority Data
Jan. 12, 2024 (CN) 2024100505353

(51) Int. Cl. G06F 30/18; G08G 5/00

(52) U.S. Cl. CPC G06F 30/18; G08G 5/20; G08G 5/727

(57) ABSTRACT

A method for runway configurations prediction of multi-airport system based on dynamic graphs, belonging to the technical field of air traffic control operation management; the method of the present invention constructs a dynamic graph model of a plurality of runway configurations in a multi-airport system, achieves prediction on runway configurations according to the dynamic graph model, is suitable for multi-airport system operation scenes and is capable of performing continuous prediction on runway configurations in all operation durations; the present invention not only allows air traffic controllers to achieve accurate runway scheduling but also provides powerful data support for making overall strategies for the multi-airport system operation.

### TECHNICAL FIELD

This invention generally relates to the technical field of air traffic control operation management, and more particularly, to a method for runway configurations prediction of multi-airport system based on dynamic graphs.

### BACKGROUND

With the explosive increase in air traffic flow, accurate prediction of multi-airport system runway configurations has become a key factor in ensuring the safety and efficiency of airport operations. In the context of globalization, airports are no longer isolated individuals but jointly form a complex multi-airport system. This transformation means that the runway configurations of a single airport may directly or indirectly affect the operations of other airports within the multi-airport system. For example, a delay aircraft at one airport may trigger a chain reaction affecting aircraft scheduling across aircraft the entire multi-airport system.

Runway configurations refer to the regulations and arrangements for the runway based on aircraft take-offs, landings and other operations aircraft within a time period.

Making reasonable predictions about the runway configurations of multi-airport system can ensure that there are appropriate time intervals and optimal conditions for aircraft to take off and land on specific runways (selected based on specific circumstances in different airports).

Factors affecting the prediction of runway configurations include a geographic location and layout of the airport, current meteorological conditions, air traffic flow, physical state of the runway, types and destinations of flights, as well as security requirements, etc.

Meanwhile, to meet the growing demand for air traffic, airports must operate efficiently. Adopting different runway configurations to optimize the use of runways allows airports to process more aircrafts, which significantly improves the throughput capacity of airports. In addition, reasonable runway management is also capable of reducing flight delays caused by runway congestion or other reasons, lower the noise and other environmental impacts of airports on surrounding areas, ensuring the maximum utilization of resources, and better coordinating air traffic flow to respond to various emergency situations. Therefore, the runway configurations are critical to safe and efficient operation of airports. Different airports may select runway configurations according to specific demands and actual needs, and the selection and use configurations of runways may also be affected by the air traffic control, weather conditions, equipment availability and other factors.

In most cases, the runway configurations are mainly changed based on fixed rules and control experience instead of being predicted using technical means, resulting in airport congestion or waste of runway resources. To improve the airport operation efficiency, technologies for predicting runway configurations have been studied. However, existing technologies merely consider prediction at a single moment, the used data is relatively single and complex interactions are ignored, leading to inaccurate prediction results. More importantly, these methods merely focus on the situation of a single airport and ignore the coupled relationship between airports in the multi-airport system, making the operation of airports inefficient.

### SUMMARY

The purpose of the present invention is to provide a method for runway configurations prediction of multi-airport system based on dynamic graphs, which constructs a dynamic graph model of a plurality of runway configurations in a multi-airport system, achieves prediction on the plurality of runway configurations according to the dynamic graph model, is suitable for multi-airport system operation scenes and is capable of performing continuous prediction on the plurality of runway configurations in all operation durations. The present invention not only allows air traffic controllers to achieve accurate runway scheduling but also provides strong data support for making overall strategies for the multi-airport system operation.

To achieve the above purpose, the present invention adopts the following technical solution: a method for runway configurations prediction of multi-airport system based on dynamic graphs, comprising the steps of:

Step 1: obtaining a plurality of runway configurations and corresponding influence factors in a multi-airport system based on historical data of the multi-airport system, and constructing a node feature matrix of the plurality of runway configurations;

Preferably, in step 1, constructing a node feature matrix, comprising:

Taking runway configuration i as a node, obtaining influence factors corresponding to the runway configuration, and establishing a node feature vi based on the influence factors:

$${}_{} = [ {1}_{} , {2}_{} , … , {NUM}_{} ]$$

wherein [symbol] represents an influence value of the node corresponding to the runway configuration i and a [symbol] [symbol] [symbol] -th influence factor, wherein [symbol] [symbol] [symbol] =1, 2, 3 . . . , NUM, and NUM represents a total number of influence factors, wherein i=1, 2, 3 . . . N, and N represents a total number of runway configurations;
Constructing a node feature matrix of the plurality of runway configurations;
Further, the influence factors corresponding to the runway configurations include the frequency of use of runway configurations, the runway configurations average duration, the correlation between runway configurations, the weather sensitivity, the air traffic flow sensitivity, the multi-airport system effect, and/or the aerodrome for triggering configurations changeover;
The runway configurations correlation is expressed as:

$${R}_{} = \frac{{}_{}}{T}$$

wherein [symbol] represents the correlation between the runway configuration i and the runway configuration j, and [symbol] represents the number of times the runway configuration i is switched to the runway configuration j, wherein i, j∈N, i≠j, and N represents the total number of runway configurations, wherein T represents a total observed time period;
The runway configurations weather sensitivity measures a correlation strength or preference between specific runway configurations and specific weather conditions;
The air traffic flow sensitivity is a frequency of use of runway configuration i under a specific air traffic flow; for example, the frequency of use of runway configuration i under a large air traffic flow, or the frequency of use of runway configuration i under a small air traffic flow;
The multi-airport system effect refers to the status and influence of an airport in the multi-airport system, and for a given airport, the effect of the airport in the multi-airport system is jointly determined by the flow correlation and distance between the airport and others;
It is worth mentioning that, the aerodrome event-driven sensitivity is the frequency of use of runway configuration i when unsafe events occur in the multi-airport system, wherein unsafe events include go-arounds, runway incursions, and low-level wind shear, among others;
Step 2: taking a configuration changeover between two runway configurations as an edge, and obtaining influence factors corresponding to the configuration changeover; subsequently, obtaining edge features based on the influence factors corresponding to the configuration changeover;
Constructing the edge feature set corresponding to the plurality of runway configurations;
It is worth mentioning that, performing configuration changeover between the two runway configurations, comprising: changing from the runway configuration i to the adjacent runway configuration j to ensure an efficient operation of aircrafts in the multi-airport system based on a specific condition (e.g., the weather condition, the air traffic flow, the aircraft safety requirement or the specific time period, etc.);
The influence factors corresponding to the configuration changeover include: the frequency of changeover between the two runway configurations, the average delay of changeover, the correlation of the frequency of changeover between the two runway configurations, the weather changeover correlation, the air traffic flow in changeover, the multi-airport system effect in changeover, and/or the aerodrome for triggering configurations changeover;
The correlation of frequency of changeover between the two runway configurations is: the probability of changing from a first runway configuration to a second runway configuration and then changing to a third runway configuration;
Assuming that one airport has three runway configurations: A, B and C, if it is observed that the airport changeovers from the runway configuration A to the runway configuration B within a specific time period and then frequently changeovers to the runway configuration C, the correlation of the changeover sequence A→B→C is relatively high;
The weather sensitivity of the changeover between the two runway configurations is the influence of a specific weather condition on an airport's changeover from one runway configuration to another; and in a specific weather condition, for example, a rainy day or a heavy fog day, the airport may changeover from the current configuration to a specific safer configuration;
It is worth mentioning that, the multi-airport system effect in changeover between the plurality of runway configurations is based on the influence of the distance between airports in the multi-airport system [symbol] and the air traffic flow, and the runway configuration i changeovers from the airport a to the airport b, where a, b∈ [symbol] , and [symbol] represents a multi-airport system consisted of a plurality of airports;
Step 3: obtaining a feature set based on the node feature matrix and the edge feature set;
Constructing a dynamic graph model, and embedding the feature set and an event-driven model into the dynamic graph model, thereby obtaining a time series dynamic graph model;
Obtaining a time series message memory of the plurality of runway configurations at the current moment by using the time series dynamic graph model;
Constructing a runway configurations prediction dynamic graph model by using the time series message memory of the plurality of runway configurations at the current moment; Preferably, obtaining a time series message memory of the plurality of runway configurations at the current moment, specifically comprising:
Constructing a dynamic graph model, and embedding the feature set and an event-driven model into the dynamic graph model, thereby obtaining a time series dynamic graph model;
Determining whether the node of the runway configuration i at the current moment t is an independent node;
It is worth mentioning that, the runway configuration i at the current moment t being an independent node indicates that the predicted next runway configuration is still the runway configuration i;
The runway configuration i being not an independent node indicates that there is a neighbor node in the runway configuration i, and the runway configuration i and the neighbor node perform configuration changeover between the runway configurations;
If the node of the runway configuration i in the current moment t is an independent node, obtaining a node feature vi (t) of the runway configuration i in the current moment t based on the node feature matrix, and inputting the node feature vᵢ (t) of the runway configuration i in the current moment t into the time series dynamic graph model, thereby obtaining global information sᵢ (t−) of the node feature vᵢ (t) of the runway configuration i before the current moment t, wherein t=1, 2, 3 . . . T, and T represents a total number of moments;
It is worth mentioning that, the global information sᵢ(t−)′ of the node feature vᵢ (t) of the runway configuration i before the current moment t is the memory corresponding to all events that occur from moment 0 to moment t;
Aggregating the global information sᵢ(t−)′ of the node feature vᵢ (t) of the runway configuration i before the current moment t and the node feature vᵢ (t) of the runway configuration i at the current moment t by using a graph attention mechanism, thereby obtaining an initial aggregation message mᵢ(t)′ of the runway configuration i at the current moment t;
Obtaining a plurality of events of the runway configuration i before the current moment t, and performing batch aggregation on the aggregation message mᵢ(t)′ of the runway configuration i at the current moment t based on the plurality of events, wherein the plurality of events corresponds to moments, and the moments corresponding to the plurality of events are in an unordered state, wherein a moment at which a latest event occurs is t, and there is a total of B events;
Obtaining an aggregation message [symbol] of the runway configuration i at the current moment t;
Performing message update propagation on the aggregation message \tilde{m}ᵢ(t)′ of the runway configuration i at the current moment t and the global information sᵢ(t−)′ of the node feature vᵢ (t) of the runway configuration i before the current moment t, thereby obtaining the global information sᵢ(t)′ of the node feature vᵢ (t) of the runway configuration i at the current moment t;
Performing message propagation on the global information sᵢ(t)′ of the node feature vᵢ (t) of the runway configuration i at the current moment t and the node feature vᵢ (t) of the runway configuration i, thereby generating a time series message memory Zᵢ₍ₜ₎′ of the independent node runway configuration i at the current moment t; if the node of the runway configuration i at the current moment t is not an independent node, obtaining the node feature vᵢ (t) of the runway configuration i at the current moment t and the node feature vⱼ(t) of the neighbor runway configuration j based on the node feature matrix and the edge feature set, and then obtaining an edge feature eᵢⱼ (t) of the runway configuration i and the runway configuration j at the current moment t, wherein i≠j, i, j∈N, and N represents the total number of runway configurations;
Inputting the node feature vᵢ (t) of the runway configuration i and the node feature vⱼ (t) of the runway configuration j into the time series dynamic graph model, thereby obtaining the global information sᵢ (t−) of the node feature vᵢ (t) of the runway configuration i before the current moment t, the global information sⱼ (t−) of the node feature vⱼ(t) of the runway configuration j before the current moment t, and the edge feature eᵢⱼ (t) at the current moment t; subsequently, aggregating the global information sᵢ (t−) of the node feature vᵢ (t) of the runway configuration i before the current moment t, the global information sⱼ (t−) of the node feature vⱼ (t) of the runway configuration j before the current moment t, the edge feature eᵢⱼ (t) at the current moment t and the node feature vᵢ (t) of the runway configuration i at the current moment t by using the graph attention mechanism, thereby obtaining a multi-node initial aggregation message mᵢ(t) of the runway configuration i at the current moment t, wherein j∈N, and N represents the total number of runway configurations;
Obtaining a plurality of events of the runway configuration i before the moment t, and performing batch aggregation on the multi-node initial aggregation message mᵢ (t) of the runway configuration i at the current moment t based on the plurality of events before the moment t, thereby obtaining a multi-node aggregation message [symbol] of the runway configuration i at the current moment t; it is worth mentioning that, the plurality of events corresponds to a plurality of moments, and the moments corresponding to the plurality of events are in an unordered state, wherein the moment at which the latest event occurs is t, and there is a total of B events;
Performing message update propagation on the multi-node aggregation message [symbol] of the runway configuration i at the current moment t, the global information sᵢ (t−) of the node feature vᵢ (t) of the runway configuration i before the current moment t, and the global information sⱼ (t−) of the node feature vⱼ (t) of the runway configuration j before the current moment t, thereby obtaining the global information sᵢ (t) of the node feature vᵢ (t) of the runway configuration i at the current moment t and the global information sⱼ (t) of the node feature vⱼ of the runway configuration j at the current moment t;
Performing message propagation on the global information sᵢ (t) of the node feature vᵢ (t) of the runway configuration i at the current moment t, the global information sⱼ (t) of the node feature vⱼ of the runway configuration j at the current moment t, the edge feature eᵢⱼ (t) at the current moment t, the node feature vᵢ (t) of the runway configuration i at the current moment t, and the node feature vⱼ (t) of the runway configuration j at the current moment t, thereby generating a time series message memory Zᵢ₍ₜ₎ of the non-independent node runway configuration i at the current moment t;
Iterating through the plurality of runway configurations, and repeating the above steps to obtain the time series message memory of the plurality of runway configurations at the current moment t;
Further, the time series message memory Zᵢ₍ₜ₎ of the non-independent node runway configuration i at the current moment t is expressed as:

$$\begin{matrix}{𝓏}_{i} ( t ) = emb ( i , t ) \\ = {\sum }_{j ∈ {N}_{k}^{i} ( [ 0 , t ] )} Attention ( {v}_{i} , {v}_{j} , {e}_{ij} ) \cdot h ( {s}_{i} ( t ) , {s}_{j} ( t ) , {e}_{ij} , {v}_{i} ( t ) , {v}_{j} ( t ) )\end{matrix}$$

wherein Zᵢ₍ₜ₎ represents the time series message memory of the non-independent node runway configuration i at the current moment t, and emb (⋅) represents an embedded function, wherein emb (i, t) represents information collected from the neighbor runway configurations of the runway configuration i at the current moment t through the graph attention mechanism, wherein Attention (⋅) represents a graph attention weight, vᵢ represents the node feature of the runway configuration i, vⱼ represents the node feature of the runway configuration j, and i=1, 2, 3 . . . N, wherein Nₖ^{l}[0,t] represents a k-ordered neighborhood of the runway configuration i during the process from the moment 0 to the moment t, wherein i, j∈N, and N represents the total number of the runway configurations, wherein k=1, 2, 3 . . . K, and K represents the total order of neighborhood, wherein eᵢⱼ represents the edge feature, wherein sⱼ (t) represents the global information of the node feature vⱼ of the runway configuration j at the current moment t, wherein sᵢ (t) represents the global information of the node feature vᵢ of the runway configuration i at the current moment t, wherein vᵢ (t) represents the node feature of the runway configuration i at the current moment t, wherein vⱼ (t) represents the node feature of the runway configuration j at the current moment t, wherein h (⋅) represents a learnable function;

$$𝒽 ( {𝓈}_{i} ( t ) , {s}_{j} ( t ) , {e}_{ij} , {v}_{i} ( t ) , {v}_{j} ( t ) ) = {α}_{ij} \cdot M L P ( {s}_{i} ( t ) ‖ {s}_{j} ( t ) ‖ {e}_{ij} ‖ {v}_{i} ( t ) ‖ {v}_{j} ( t ) )$$

wherein [symbol] represents an attention coefficient, which is obtained through calculation based on the node features of the runway configuration i and the runway configuration j, wherein MLP (⋅) represents a nonlinear function, which is used for learning a complex nonlinear representation from the input features;
According to the technical solution of the present invention, the aggregation message of the runway configuration i at the current moment t is obtained based on the graph attention mechanism, which is used for capturing a key feature of the node at a specific moment and a relationship between the node and other nodes; the initial aggregation messages of the runway configurations at different time points are aggregated to reflect a dynamic variation of the node along the time variation, and further, on the basis of maintaining the time series information of the node, node features at different time points are integrated; the initial aggregation messages of the runway configurations at different time points are aggregated in the time dimension for obtaining an aggregation message, which is capable of more comprehensively reflecting the dynamic features of the node along the time variation; this two-stage aggregation method helps to more accurately capture and understand the behavior of the node in a time series, thereby providing support for time-and-event-based prediction models;
The present invention employs an event-driven mechanism that triggers prediction based on real-time variation in data features; the core of this method is to monitor key data indicators and to immediately perform predictive analysis when these indicators show significant variation; for example, a new flight plan added to the system and a sudden variation of meteorological conditions that affects the use of the runway are all events that trigger the prediction update; the dynamic graph model captures these variations in real time, and immediately re-evaluates the runway configurations of the multi-airport system to generate an updated prediction; this method enables the prediction model to more sensitively respond to dynamic variations in actual use, improve the effectiveness and accuracy of prediction, and avoid unnecessary calculation when the data is relatively static, thereby achieving best resource usage and rapid response;
The event-driven prediction means that an update of the model is triggered based on the occurrence of an event rather than a fixed time interval; under such circumstances, the event may be an arrangement or cancellation of a new flight, a predicted weather event such as a coming storm, an unusual flight delay or emergency, or a runway state variation; when an event occurs, the dynamic graph model receives new data points and then updates the prediction based on these data points; this method is more flexible and highly adaptable and is capable of providing more accurate information in time for operation decisions;
Step 4: predicting runway configurations at a next moment of the runway configuration i at the current moment t based on the runway configurations prediction dynamic graph model and the loss function, and taking each obtained runway configurations as the prediction probability of the runway configurations at the next moment of the runway configuration i at the current moment t, thereby obtaining a plurality of prediction probabilities;
Setting a threshold, comparing the plurality of prediction probabilities with the threshold, and taking the runway configurations greater than the threshold as the prediction result of the runway configurations at the next moment of the runway configuration i at the current moment t, thereby obtaining a plurality of prediction results corresponding to the runway configurations at the next moment of the runway configuration i at the current moment t;
Preferably, when the runway configuration i at the current moment t is a non-independent node, the prediction probability of the runway configurations at the next moment of the non-independent node runway configuration i at the current moment t is expressed as:

$${P}_{iq , t + 1} = \qquad ( {Z}_{i ( t )}^{T} {Z}_{q ( t )} )$$

wherein P_{iq,t+1} represents that the runway configurations of the non-independent node runway configuration i at the next moment t+1 is the prediction probability of the runway configuration q, wherein [symbol] (⋅) represents a sigmoid function, wherein i, q∈N, and N represents the total number of the runway configurations, wherein Z_{q(t)} represents the time series message memory of the non-independent node runway configuration q at the current moment t, wherein Zᵢ₍ₜ₎ represents the time series message memory of the non-independent node runway configuration i at the current moment t, wherein T represents a transpose, and
Zₗ₍ₜ^{T}Z_{q(t)} represents a dot product vector of the non-independent node runway configurations i and q at the current t;
The corresponding loss function when the runway configuration i at the current t is a non-independent node is expressed as:

[symbol]

=− [symbol] _{,t+1} log(P_{iq,t+1})−(1− [symbol] _{,t+1})log(1− [symbol] _{,t+1})

wherein y_{iq, t+1} represents a link relationship between the non-independent node runway configuration i and runway configuration q at the moment t+1, y_{iq, t+1} indicates that the link exists, and y_{iq, t+1}=0 indicates that the link does not exist;
When the runway configuration i at the current moment t is an independent node, the prediction probability of the runway configurations at the next moment of the independent node runway configuration i at the current moment t is expressed as:

$${P}_{iq , t + 1}^{′} = \qquad ( {Z}_{{i ( t )}^{′}}^{T} {Z}_{{q ( t )}^{′}} )$$

wherein P′_{i,q,t+1} represents that the runway configurations of the independent node runway configuration i at the next moment t+1 is the prediction probability of the runway configuration q, wherein [symbol] (⋅) represents a sigmoid function, wherein i, q∈N, and N [symbol] represents the total number of the runway configurations, wherein Z_{q(θ)′} represents the time series message memory of the independent node runway configuration q at the current moment t, wherein Z_{i(t)′} represents the time series message memory of the independent node runway configuration i at the current moment t, wherein T represents the transpose, and Z_{i(t)′}^{T}Z_{q(t)′} represents the dot product vector of the independent node runway configurations i and q at the current t;
Further, setting a threshold based on the historical runway usage data, flight plan data, environment and meteorological data, operational constraints and rules, runway condition data, node and link relationship data and label data.

Compared with the prior art, the present invention has the following advantages:
1) The present invention comprehensively considers the complexity and diversity of the operation of the multi-airport system, is suitable for various multi-airport system operation scenes by means of combining the time, the network structure inside the multi-airport system and the feature information of the multi-airport system, and is capable of realizing high-precision runway configurations prediction and providing an accurate runway configurations suggestion for a controller especially when the airport traffic flow or the weather condition varies;
2) By combining the node features and edge features, the present invention realizes a quick response to the real-time data, thereby helping the multi-airport system management to make more scientific and reasonable operation strategies;
3) According to the present invention, runway scheduling is optimized, unnecessary delay is avoided, and the overall operation efficiency and safety of the multi-airport system are improved;
4) The runway configurations prediction method of the present invention possesses high expansibility, which is suitable for more large-scale multi-airport systems or introducing more features and data sources, so that the requirements of continuous development of multi-airport system operation are met.

### BRIEF DESCRIPTION OF THE DRAWINGS

The drawings are merely used for the purpose of illustration but are not intended to limit the present invention.

FIG. 1 is a schematic diagram illustrating the event-driven time model of the present invention;

FIG. 2 is a flowchart of obtaining a time series message memory of the runway configurations of the present invention;

FIG. 3 is a schematic diagram illustrating the runway configurations prediction dynamic graph model of the present invention.

### DETAILED DESCRIPTION

To allow the purposes, features and benefits of the present invention to be better understood, a detailed description of the present invention is provided below in combination with the drawings and specific embodiments. It should be noted that the embodiments of the present invention and the features in the embodiments may be combined with each other without conflict. In addition, to allow the details of the present invention to be better understood, the present invention may also be implemented in other ways different from those described herein. Therefore, the scope of the present invention is not limited by the specific embodiments described below.

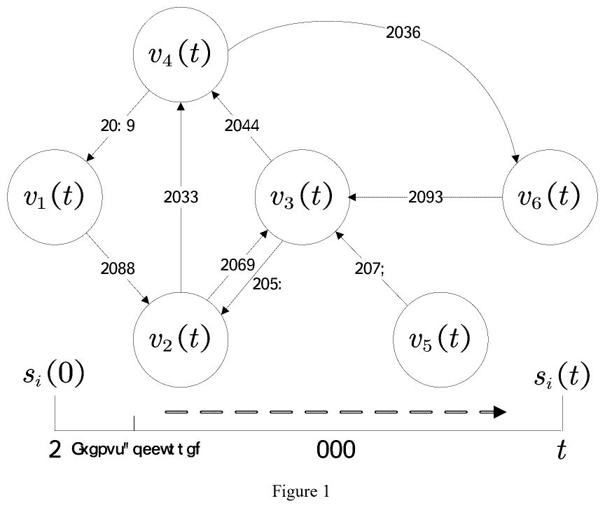

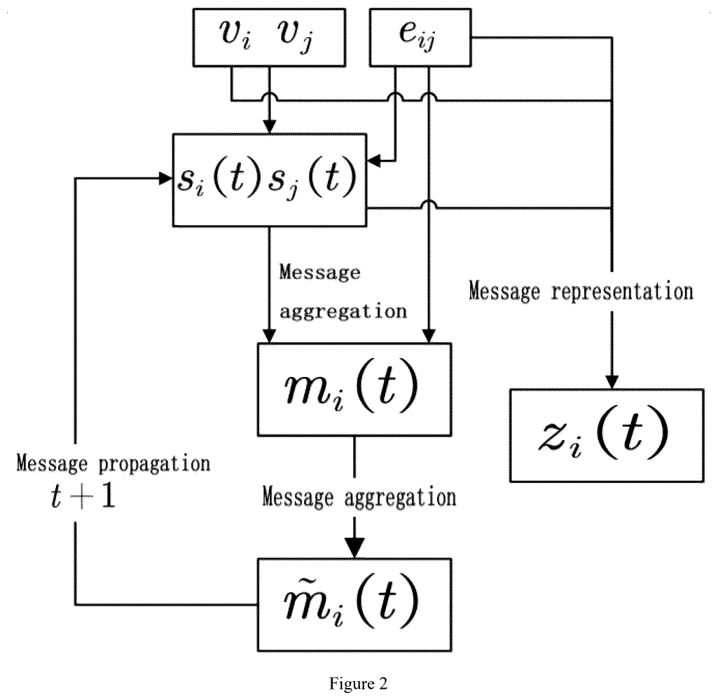

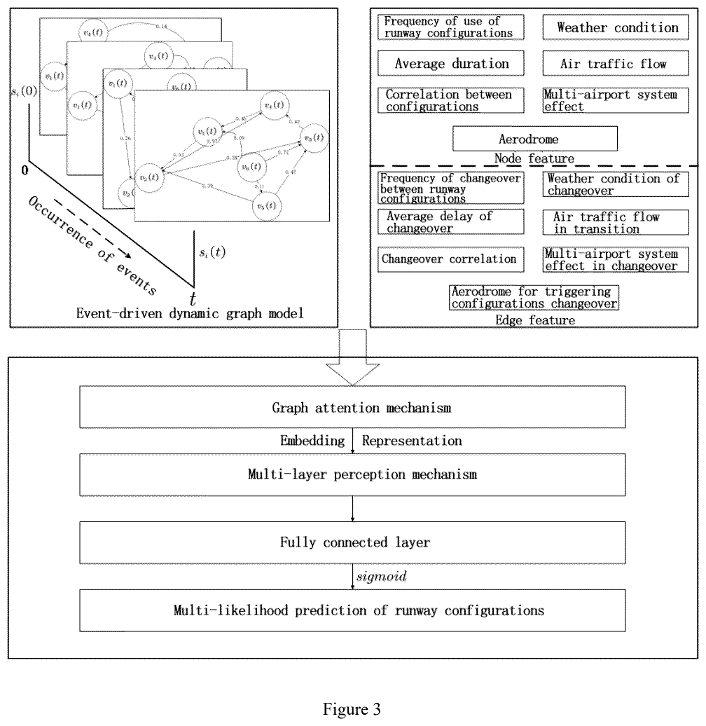

In one embodiment of the present invention, referring to FIGS. 1-3, the present invention provides a method for runway configurations prediction of multi-airport system based on dynamic graphs. To illustrate the specific implementation of the method of the present invention, the aforesaid technical solution of the present invention is described in detail below in an embodiment. The method of the present invention, comprising the steps of:
Step 1: obtaining a plurality of runway configurations and corresponding influence factors in a multi-airport system based on historical data of the multi-airport system, and constructing a node feature matrix of the plurality of runway configurations;
Preferably, in step 1, constructing a node feature matrix, comprising:
Taking a runway configuration i as a node, obtaining influence factors corresponding to the runway configurations, and establishing a node feature vᵢ based on the influence factors:

$${}_{} = [ {1}_{} , {2}_{} , … , {NUM}_{} ]$$

wherein [symbol] represents an influence value of the node corresponding to the runway configurations i and a [symbol] [symbol] [symbol] -th influence factor, wherein [symbol] [symbol] [symbol] =1, 2, 3 . . . NUM, and NUM represents a total number of influence factors, wherein i=1, 2, 3 . . . N, and N represents a total number of runway configurations;
Constructing a node feature matrix of the plurality of runway configurations;
Further, the influence factors corresponding to the runway configurations include a frequency of use of runway configurations, a runway configurations average duration, a runway configurations correlation, a weather sensitivity, an air traffic flow sensitivity, a multi-airport system effect, and/or an aerodrome event-driven sensitivity;
The runway configurations correlation is expressed as:

$${R}_{} = \frac{{}_{}}{T}$$

wherein [symbol] represents the correlation between the runway configuration i and the runway configuration j, and [symbol] represents the number of times the runway configuration i is switched to the runway configuration j, wherein i, j∈N, i≠j, and N represents the total number of runway configurations, wherein T represents a total time period for predicting runway configurations;
The runway configurations weather sensitivity measures a correlation strength or preference between specific runway configurations and specific weather conditions;
The air traffic flow sensitivity is a frequency of use of runway configuration i under a specific air traffic flow; for example, the frequency of use of runway configuration i under a large air traffic flow, or the frequency of use of runway configuration i under a small air traffic flow;
The multi-airport system effect is the position and influence of an airport in the multi-airport system, and for a given airport, the effect of the airport in the multi-airport system is jointly determined by the flow correlation and distance between the airport and other airports;
It is worth mentioning that, the aerodrome event-driven sensitivity is the frequency of use of runway configuration i when unsafe events occur in the multi-airport system, wherein unsafe events include an aircraft's losing control in the air, an unsafe runway, and a controllable aircraft's hitting the ground;
Step 2: taking a changeover between two runway configurations as an edge, and obtaining influence factors corresponding to the configuration changeover; subsequently, obtaining an edge feature based on the influence factors corresponding to the configuration changeover;
Constructing an edge feature set corresponding to the plurality of runway configurations;
It is worth mentioning that, performing configurations changeover between the two runway configurations, comprising: changing from the runway configuration i to the adjacent runway configuration j to ensure an efficient operation of aircrafts in the multi-airport system based on a specific condition (e.g., a weather condition, an air traffic volume, an aircraft safety requirement or a specific time period, etc.);
The influence factors corresponding to the configurations changeover include: the frequency of changeover between the two runway configurations, the average delay of changeover, the correlation of the frequency of changeover between the two runway configurations, the weather changeover correlation, the air traffic flow in changeover, the multi-airport system effect in changeover, and/or the aerodrome for triggering configurations changeover;
The correlation of frequency of changeover between the two runway configurations is: the probability of changing from a first runway configuration to a second runway configuration and then changing to a third runway configuration;
Assuming that one airport has three runway configurations: A, B and C, if it is observed that the airport changeovers from the runway configuration A to the runway configuration B within a specific time period and then frequently changeovers to the runway configuration C, the correlation of the changeover sequence A→B→C is relatively high;
The weather sensitivity of the changeover between the two runway configurations is the influence of a specific weather condition on an airport's changeover from one runway configuration to another; and in a specific weather condition, for example, a rainy day or a heavy fog day, the airport may changeover from the current configuration to specific safer configuration;
It is worth mentioning that, the multi-airport system effect in changeover between the plurality of runway configurations is based on the influence of the distance between airports in the multi-airport system [symbol] and the air traffic flow, and the runway configuration i changeover from the airport a to the airport b, where a, b∈ [symbol] , and [symbol] represents a multi-airport system consisted of a plurality of airports;
Step 3: obtaining a feature set based on the node feature matrix and the edge feature set;
Constructing a dynamic graph model, and embedding the feature set and an event-driven time model into the dynamic graph model, thereby obtaining a time series dynamic graph model;
Obtaining a time series message memory of the plurality of runway configurations at the current moment by using the time series dynamic graph model;
Constructing a runway configuration prediction dynamic graph model by using the time series message memory of the plurality of runway configurations at the current moment;
Preferably, obtaining a time series message memory of the plurality of runway configurations at the current moment, specifically comprising:
Constructing a dynamic graph model, and embedding the feature set and an event-driven time model into the dynamic graph model, thereby obtaining a time series dynamic graph model;
Determining whether the node of the runway configuration i at the current moment t is an independent node;
It is worth mentioning that, the runway configuration i at the current moment t being an independent node indicates that the predicted next runway configuration is still the runway configuration i;
The runway configuration i being not an independent node indicates that there is a neighbor node in the runway configuration i, and the runway configuration i and the neighbor node perform configuration changeover between the runway configurations;
If the node of the runway configuration i in the current moment t is an independent node, obtaining a node feature vᵢ (t) of the runway configuration i in the current moment t based on the node feature matrix, and inputting the node feature vᵢ (t) of the runway configuration i in the current moment t into the time series dynamic graph model, thereby obtaining global information sᵢ (t−) of the node feature vᵢ (t) of the runway configuration i before the current moment t, wherein t=1, 2, 3 . . . T, and T represents a total number of moments;
It is worth mentioning that, the global information sᵢ(t−)′ of the node feature vᵢ (t) of the runway configuration i before the current moment t is the memory corresponding to all events that occur from moment 0 to moment t;
Aggregating the global information sᵢ(t−)′ of the node feature vᵢ (t) of the runway configuration i before the current moment t and the node feature vᵢ (t) of the runway configuration i at the current moment t by using a graph attention mechanism, thereby obtaining an initial aggregation message mᵢ(t)′ of the runway configuration i at the current moment t;
Obtaining a plurality of events of the runway configuration i before the current moment t, and performing batch aggregation on the aggregation message mᵢ(t)′ of the runway configuration i at the current moment t based on the plurality of events, wherein the plurality of events corresponds to a plurality of moments, and the moments corresponding to the plurality of events are in an unordered state, wherein a moment at which a latest event occurs is t, and there is a total of B events;
Obtaining an aggregation message [symbol] of the runway configuration i at the current moment t;
Performing message update propagation on the aggregation message [symbol] of the runway configuration i at the current moment t and the global information sᵢ(t−)′ of the node feature vᵢ (t) of the runway configuration i before the current moment t, thereby obtaining the global information sᵢ(t)′ of the node feature vᵢ (t) of the runway configuration i at the current moment t;
Performing message propagation on the global information sᵢ(t)′ of the node feature vᵢ (t) of the runway configuration i at the current moment t and the node feature vᵢ (t) of the runway configuration i, thereby generating a time series message memory Zᵢ₍ₜ₎′ of the independent node runway configuration i at the current moment t; if the node of the runway configuration i at the current moment t is not an independent node, obtaining the node feature vᵢ (t) of the runway configuration i at the current moment t and the node feature vⱼ (t) of the neighbor runway configurations j based on the node feature matrix and the edge feature set, and then obtaining an edge feature eᵢⱼ (t) of the runway configuration i and the runway configuration j at the current moment t, wherein i≠j, i, j∈N, and N represents the total number of runway configurations;
Inputting the node feature vᵢ (t) of the runway configuration i and the node feature vⱼ (t) of the runway configuration j into the time series dynamic graph model, thereby obtaining the global information sᵢ (t−) of the node feature vᵢ (t) of the runway configuration i before the current moment t, the global information sⱼ (t−) of the node feature vⱼ (t) of the runway configurations j before the current moment t, and the edge feature eᵢⱼ (t) at the current moment t; subsequently, aggregating the global information sᵢ (t−) of the node feature vᵢ (t) of the runway configuration i before the current moment t, the global information sⱼ (t−) of the node feature vⱼ (t) of the runway configuration j before the current moment t, the edge feature eᵢⱼ (t) at the current moment t and the node feature vᵢ (t) of the runway configuration i at the current moment t by using the graph attention mechanism, thereby obtaining a multi-node initial aggregation message mᵢ(t) of the runway configuration i at the current moment t, wherein j∈N, and N represents the total number of runway configurations;
Obtaining a plurality of events of the runway configuration i before the moment t, and performing batch aggregation on the multi-node initial aggregation message mᵢ (t) of the runway configuration i at the current moment t based on the plurality of events before the moment t, thereby obtaining a multi-node aggregation message [symbol] of the runway configuration i at the current moment t; it is worth mentioning that, the plurality of events corresponds to a plurality of moments, and the moments corresponding to the plurality of events are in an unordered state, wherein the moment at which the latest event occurs is t, and there is a total of B events;
Performing message update propagation on the multi-node aggregation message [symbol] of the runway configuration i at the current moment t, the global information sᵢ (t−) of the node feature vᵢ (t) of the runway configuration i before the current moment t, and the global information sⱼ (t−) of the node feature vⱼ (t) of the runway configuration j before the current moment t, thereby obtaining the global information sᵢ (t) of the node feature vᵢ (t) of the runway configuration i at the current moment t and the global information sⱼ (t) of the node feature vⱼ of the runway configuration j at the current moment t;
Performing message propagation on the global information sᵢ (t) of the node feature vᵢ (t) of the runway configuration i at the current moment t, the global information sⱼ (t) of the node feature vⱼ of the runway configuration j at the current moment t, the edge feature eᵢⱼ (t) at the current moment t, the node feature vᵢ (t) of the runway configuration i at the current moment t, and the node feature vⱼ (t) of the runway configuration j at the current moment t, thereby generating a time series message memory Zᵢ₍ₜ₎ of the non-independent node runway configuration i at the current moment t;
Iterating through the plurality of runway configurations, and repeating the above steps to obtain the time series message memory of the plurality of runway configurations at the current moment t;
Further, the time series message memory Zᵢ₍ₜ₎ of the non-independent node runway configuration i at the current moment t is expressed as:

$$\begin{matrix}{𝓏}_{i} ( t ) = emb ( i , t ) \\ = {\sum }_{j ∈ {N}_{k}^{i} ( [ 0 , t ] )} Attention ( {v}_{i} , {v}_{j} , {e}_{ij} ) \cdot h ( {s}_{i} ( t ) , {s}_{j} ( t ) , {e}_{ij} , {v}_{i} ( t ) , {v}_{j} ( t ) )\end{matrix}$$

wherein Zᵢ₍ₜ₎ represents the time series message memory of the non-independent node runway configuration i at the current moment t, and emb (⋅) represents an embedded function, wherein emb (i, t) represents information collected from the neighbor runway configurations of the runway configuration i at the current moment t through the graph attention mechanism, wherein Attention (⋅) represents a graph attention weight, vᵢ represents the node feature of the runway configuration i, vⱼ represents the node feature of the runway configuration j, and i=1, 2, 3 . . . N, wherein Nₖⁱ[0,t] represents a k-ordered neighborhood of the runway configuration i during the process from the moment 0 to the moment t, wherein i, j∈N, and N represents the total number of the runway configurations, wherein k=1, 2, 3 . . . K, and K represents the total order of neighborhood, wherein eᵢⱼ represents the edge feature, wherein sⱼ (t) represents the global information of the node feature vⱼ of the runway configuration j at the current moment t, wherein sᵢ (t) represents the global information of the node feature vᵢ of the runway configuration i at the current moment t, wherein vᵢ (t) represents the node feature of the runway configuration i at the current moment t, wherein vⱼ (t) represents the node feature of the runway configuration j at the current moment t, wherein h (⋅) represents a learnable function;

$$𝒽 ( {𝓈}_{i} ( t ) , {s}_{j} ( t ) , {e}_{ij} , {v}_{i} ( t ) , {v}_{j} ( t ) ) = {α}_{ij} \cdot M L P ( {s}_{i} ( t ) ‖ {s}_{j} ( t ) ‖ {e}_{ij} ‖ {v}_{i} ( t ) ‖ {v}_{j} ( t ) )$$

wherein [symbol] represents an attention coefficient, which is obtained through calculation based on the node features of the runway configuration i and the runway configuration j, wherein MLP (⋅) represents a nonlinear function, which is used for learning a complex nonlinear representation from the input features;
According to the technical solution of the present invention, the aggregation message of the runway configuration i at the current moment t is obtained based on the graph attention mechanism, which is used for capturing a key feature of the node at a specific moment and a relationship between the node and other nodes; the initial aggregation messages of the runway configurations at different time points are aggregated to reflect a dynamic variation of the node along the time variation, and further, on the basis of maintaining the time series information of the node, node features at different time points are integrated; the initial aggregation messages of the runway configurations at different time points are aggregated in the time dimension for obtaining an aggregation message, which is capable of more comprehensively reflecting the dynamic features of the node along the time variation; this two-stage aggregation method helps to more accurately capture and understand the behavior of the node in a time series, thereby providing support for time-and-event-based prediction models;
The present invention employs an event-triggering mechanism that triggers prediction based on real-time variation in data features; the core of this method is to monitor key data indicators and to immediately perform predictive analysis when these indicators show significant variation; for example, a new flight plan added to the system and a sudden variation of meteorological conditions that affects the use of the runway are all events that trigger the prediction update; the dynamic graph model captures these variations in real time, and immediately re-evaluates the runway configurations of the multi-airport system to generate an updated prediction; this method enables the prediction model to more sensitively respond to dynamic variations in actual use, improve the effectiveness and accuracy of prediction, and avoid unnecessary calculation when the data is relatively static, thereby achieving best resource usage and rapid response;
The event-triggering prediction means that an update of the model is triggered based on the occurrence of an event rather than a fixed time interval; under such circumstances, the event may be an arrangement or cancellation of a new flight, a predicted weather event such as a coming storm, an unusual flight delay or emergency, or a runway state variation; when an event occurs, the dynamic graph model receives new data points and then updates the prediction based on these data points; this method is more flexible and highly adaptable and is capable of providing more accurate information in time for operation decisions;
Step 4: predicting runway configurations at a next moment of the runway configuration i at the current moment t based on the runway configurations prediction dynamic graph model and the loss function, and taking each obtained runway configurations as the prediction probability of the runway configurations at the next moment of the runway configuration i at the current moment t, thereby obtaining a plurality of prediction probabilities;
Setting a threshold, comparing the plurality of prediction probabilities with the threshold, and taking the runway configurations greater than the threshold as the prediction result of the runway configurations at the next moment of the runway configuration i at the current moment t, thereby obtaining a plurality of prediction results corresponding to the runway configurations at the next moment of the runway configuration i at the current moment t;
Preferably, when the runway configuration i at the current moment t is a non-independent node, the prediction probability of the runway configurations at the next moment of the non-independent node runway configuration i at the current moment t is expressed as:

$${P}_{iq , t + 1} = \qquad ( {Z}_{i ( t )}^{T} {Z}_{q ( t )} )$$

wherein P_{iq,t+1} represents that the runway configurations of the non-independent node runway configuration i at the next moment t+1 is the prediction probability of the runway configuration q, wherein [symbol] (⋅) represents a sigmoid function, wherein i, q∈N, and N represents the total number of the runway configurations, wherein Z_{q(t)} represents the time series message memory of the non-independent node runway configuration q at the current moment t, wherein Zᵢ₍ₜ₎ represents the time series message memory of the non-independent node runway configuration i at the current moment t, wherein T represents a transpose, and Zᵢ₍ₜ₎^{T}Z_{q(t)} represents a dot product vector of the non-independent node runway configurations i and q at the current t;
The corresponding loss function when the runway configuration i at the current t is a non-independent node is expressed as:

$$ℒ = {y}_{iq , t + 1} log ( {P}_{iq , t + 1} ) - ( 1 - {y}_{iq , t - 1} ) log ( 1 - {P}_{iq , t + 1} )$$

wherein y_{iq, t+1} represents a link relationship between the non-independent node runway configuration i and runway configuration q at the moment t+1, y_{iq, t+1} indicates that the link exists, and y_{iq, t+1}=0 indicates that the link does not exist;
When the runway configuration i at the current moment t is an independent node, the prediction probability of the runway configurations at the next moment of the independent node runway configuration i at the current moment t is expressed as:

$${P}_{iq , t + 1}^{′} = \qquad ( {Z}_{{i ( t )}^{′}}^{T} {Z}_{{q ( t )}^{′}} )$$

wherein P′_{iq,t+1} represents that the runway configurations of the independent node runway configuration i at the next moment t+1 is the prediction probability of the runway configuration q, wherein [symbol] (⋅) represents a sigmoid function, wherein i, q∈N, and N [symbol] represents the total number of the runway configurations, wherein Z_{q(t)′} represents the time series message memory of the independent node runway configuration q at the current moment t, wherein Z_{i(t)′} represents the time series message memory of the independent node runway configuration i at the current moment t, wherein T represents the transpose, and represents the dot product vector of the independent node runway configurations Z_{i(t)′}^{T}Z_{q(t)′} and q at the current t;
Further, setting a threshold based on the historical runway usage data, flight plan data, environment and meteorological data, operational constraints and rules, runway condition data, node and link relationship data and label data.

The above is merely a preferred embodiment of the present invention, and the scope of the present invention is not limited to this. Any changes or replacements made by those skilled in the art within the scope of the disclosed technology of the present invention shall fall into the scope defined by the claims of the present invention.

What is claimed is:

1. A method for runway configurations prediction of multi-airport system based on dynamic graphs, comprising:
step 1: obtaining a plurality of runway configurations and corresponding influence factors in a multi-airport system based on historical operational data fused with real-time Automatic Dependent Surveillance-Broadcast (ADS-B) data, and constructing a node feature matrix through real-time ADS-B data fusion, wherein said node feature matrix comprises runway physical parameters and operational metrics reflecting real-time operational conditions and multi-airport interactions;
step 2: defining a runway configuration changeover between two runway configurations as an edge specifically for performing link prediction tasks, wherein said link prediction explicitly involves predicting timing and target runway configurations transitions from a current runway operational mode to a subsequent runway operational mode; obtaining influence factors corresponding to the runway configuration changeover; subsequently, obtaining an edge feature based on the influence factors corresponding to the configuration changeover;
step 3: constructing a spatiotemporal dynamic graph model specifically designed for runway configuration prediction within complex multi-airport systems, wherein the constructed model incorporates:
a) a specially designed event-driven adaptive time window mechanism, explicitly synchronized with real-time Notices to Airmen (NOTAM) updates, automatically adjusting data aggregation intervals based on real-time operational alerts, thereby ensuring timely responsiveness to high-priority operational events unique to multi-airport environments, such as emergency runway closures, weather-induced runway limitations, and traffic congestion events communicated digitally via structured NOTAM interfaces;
b) a dedicated topology-aware graph attention aggregation mechanism, which explicitly accounts for complex airspace interactions and operational dependencies unique to multi-airport environments, adaptively weighting and prioritizing graph messages based on clearly defined operational factors, including airport-specific operational priority levels, geographic proximity constraints, and inter-runway dependency relationships;
wherein said adaptive mechanisms overcome traditional limitations of single-airport runway prediction methods that typically fail to consider inter-airport airspace complexity and geographic restrictions;
wherein the dynamic graph model further employs a specifically designed event-priority message caching and propagation strategy, ensuring immediate propagation of critical runway configuration updates triggered by real-time operational events, including emergency runway closures, rapid weather condition shifts, and congestion alerts;
subsequently, performing iterative message propagation:
a) for independent runway configuration nodes, automatically aggregating node features and historical runway event data through iterative message propagation, explicitly leveraging historical and real-time event data;
b) for non-independent runway configuration nodes, explicitly integrating adjacent runway configuration data and associated edge features, performing iterative message propagation governed by said specialized adaptive memory mechanisms and priority rules;
thereby generating complete and accurate time series message memories for all runway configuration nodes, thus practically enabling simultaneous and accurate predictions of multiple alternative runway operational states and their precise transition timings within multi-airport air traffic control operations, explicitly resolving geographic and airspace management complexities not addressed by existing single-airport prediction methods; and
step 4: -predicting runway configuration states for a next moment t+1 based on the specialized runway configurations prediction dynamic graph model, wherein the prediction is explicitly performed through a specially designed loss function incorporating targeted penalty terms for runway configuration switching errors, thereby ensuring practical enhancement in prediction robustness and accuracy; wherein said dynamic graph model uniquely enables simultaneous real-time prediction of multiple candidate runway configurations and their corresponding precise transition timings, thus effectively overcoming existing technical limitations associated with traditional single-airport runway prediction methods incapable of handling multi-airport operational complexities; subsequently generating prediction results explicitly as digital control signals, wherein a threshold-based selection mechanism automatically determines predicted runway configurations and their associated transition timings, directly triggering the automated issuance of taxiway clearance instructions communicated electronically to the airport surface movement radar subsystem, thereby practically integrating runway configuration predictions into real-time multi-airport air traffic control operations, substantially enhancing system-wide safety, operational efficiency, and responsiveness;
setting a threshold based on the historical runway usage data, flight plan data, environment and meteorological data, operational constraints and rules, runway condition data, node and link relationship data and label data.

2. The method for runway configurations prediction of multi-airport system based on dynamic graphs of claim 1, wherein the influence factors corresponding to the runway configurations in step 1 are specifically obtained via automated digital interfaces from meteorological monitoring systems, aeronautical information management systems providing structured NOTAM messages, and airline operational databases integrated through secure application programming interfaces (APIs); wherein said influence factors explicitly comprise runway-specific operational metrics such as frequency of runway configuration use, historical runway configurations average duration recorded electronically, correlations between runway configurations derived from digital operational archives, real-time computed meteorological sensitivity indices based on electronic weather updates, dynamically calculated air traffic flow sensitivity metrics integrated with ATC automation systems, multi-airport interdependency indicators computed from interconnected airport operational systems, and aerodrome event-driven sensitivity parameters automatically extracted and prioritized through the adaptive data aggregation mechanism, thus practically integrating the data collection step into an automated and specialized air traffic management technological framework that surpasses mere abstract data gathering and mathematical calculations.

3. The method for runway configurations prediction of multi-airport system based on dynamic graphs of claim 2, wherein the influence factors corresponding to the configuration changeover are automatically and specifically determined through structured digital interfaces integrated with real-time ATC operational systems, wherein said factors objectively reflect physical and operational constraints inherent in runway design, airport operational safety requirements, and multi-airport airspace management regulations, explicitly comprising runway configuration switching frequencies derived from structured ATC historical databases, average operational delay durations objectively measured through automated runway monitoring systems, weather condition transition thresholds predetermined by runway design specifications and automatically updated through integrated meteorological data feeds, real-time air traffic flow constraints dynamically calculated and integrated via ATC traffic flow management automation systems, multi-airport interdependency indicators computationally derived from regulated airspace interaction constraints, and aerodrome-specific triggering events automatically prioritized through structured NOTAM processing.

4. (canceled)

5. The method for runway configurations prediction of multi-airport system based on dynamic graphs of claim 41 wherein the time series message memory Zᵢ₍ₜ₎ of the runway configuration node i at the current moment t is is automatically constructed by a specialized spatiotemporal dynamic graph embedding approach, explicitly designed to handle multi-airport airspace coordination challenges arising from airspace congestion, inter-airport operational conflicts, and real-time changes in meteorological conditions; wherein said embedding method uniquely employs an adaptive event-driven message aggregation and propagation strategy integrated with an airspace conflict-aware priority mechanism, explicitly accounting for critical operational constraints such as simultaneous runway occupancy conflicts and inter-airport runway interdependencies, thereby providing practical resolution to airspace management limitations inherent in traditional spatiotemporal dynamic graph models that do not specifically address air traffic control operational constraints, wherein said memory is expressed mathematically as:
$$\begin{matrix}{𝓏}_{i} ( t ) = emb ( i , t ) \\ = {\sum }_{j ∈ {N}_{k}^{i} ( [ 0 , t ] )} Attention ( {v}_{i} , {v}_{j} , {e}_{ij} ) \cdot h ( {s}_{i} ( t ) , {s}_{j} ( t ) , {e}_{ij} , {v}_{i} ( t ) , {v}_{j} ( t ) )\end{matrix}$$
wherein the function emb (i.) represents an automated embedding operation explicitly implemented by specialized computing infrastructure, practically enabling real-time, parallelized integration of runway node and adjacent runway configuration edge data, mapping these node and edge data into a high-dimensional feature space optimized for accurately capturing complex operational dependencies within multi-airport airspace management; wherein the attention mechanism Attention (⋅) specifically treats node features vᵢ, vⱼ, and edge features eᵢⱼ as query-key-value parameters, thereby explicitly prioritizing critical runway configuration messages based on operational urgency levels automatically determined from real-time runway usage constraints, airspace topology rules, and inter-airport dependencies, substantially overcoming limitations of conventional single-airport approaches that lack operational prioritization capabilities;
wherein vᵢ represents the node feature of the runway configuration i, and vⱼ represents the node feature of the runway configuration j, with i=1, 2, 3 . . . N; wherein node neighborhoods Nᵢ₍ₜ₎ⁱ[0,t] are explicitly defined using k-ordered neighborhood structure of the runway configuration i during the process from the moment 0 to the moment t, which systematically captures indirect yet operationally significant interactions between runway configurations, practically reflecting airspace topology constraints and multi-airport dependencies beyond immediate adjacency; wherein i, i∈N, and N represents the total number of the runway configurations, wherein eᵢⱼ represents the edge feature;
wherein vᵢ(t) represents the node feature of the runway configuration i at the current moment t, wherein vⱼ(t) represents the node feature of the runway configuration j at the current moment t, as well as edge features eᵢⱼ, are objectively and automatically derived from airport-specific databases and real-time digital sensor systems reflecting runway operational states and configuration switching constraints, specifically tailored to multi-airport system scenarios constrained by geographical proximity and shared airspace management;
Nₖⁱ[0,t] wherein the global state vectors sᵢ(t) and sⱼ(t) are automatically and objectively computed from structured events updates and digital operational data feeds, enabling real-time integration of multi-airport interactions and event-driven priorities; wherein said vectors are initially aggregated into node messages mᵢ (t) via a topology-aware graph attention mechanism, which explicitly incorporates node features vᵢ(t), vⱼ(t), edge features eᵢⱼ, and global state vectors sᵢ(t), sⱼ(t); subsequently, the aggregated node messages mᵢ (t) are refined into updated node messages ^{˜}m (t) using an adaptive temporal slicing strategy, wherein message aggregation intervals are dynamically adjusted based on operational event priorities and real-time conditions, practically addressing air traffic management challenges such as sudden meteorological disruptions, emergency runway closures, and complex inter-airport dependencies, significantly improving the prediction stability, robustness, and real-time responsiveness of multi-airport runway configuration forecasts:
wherein the method practically predicts multiple alternative runway configurations simultaneously, explicitly generating predictions of both future runway operational modes and associated configuration transition timing, thereby significantly surpassing capabilities of existing airport operational prediction systems confined to single-airport scenarios; and
wherein h (⋅) represents a specialized nonlinear transformation function explicitly implemented via multilayer neural network modules integrated into the computing infrastructure, practically enabling nonlinear mapping from aggregated operational data into meaningful predictions of runway operational states and transitions timings.

6. (canceled)

7. The method for runway configurations prediction of multi-airport system based on dynamic graphs of claim 5, wherein the prediction probability of the runway configurations at the next moment of the non-independent node runway configuration i at the current moment t is expressed as:
$${P}_{iq , t + 1} = \qquad ( {Z}_{i ( t )}^{T} {Z}_{q ( t )} )$$
wherein P_{iq,t+1} represents that the runway configurations of the non-independent node runway configuration i at the next moment t+1 is the prediction probability of the runway configuration q, wherein δ (⋅) represents a sigmoid activation function, wherein i, q∈N, and N represents the total number of the runway configurations, wherein Z_{q(t)} represents the time series message memory of the non-independent node runway configuration q at the current moment t, wherein Zᵢ₍ₜ₎ represents the time series message memory of the non-independent node runway configuration i at the current moment t, said memories explicitly generated through an event-driven adaptive time window mechanism that dynamically adjusts message propagation intervals according to real-time operational events updates, thus practically enabling accurate, responsive predictions of runway configuration transitions; wherein T represents transpose, and Zᵢ₍ₜ₎^{T}Z_{q(t)} represents the vector dot product reflecting the degree of operational similarity and interaction intensity between the runway configurations i and a at the current moment t.
